(19) United States
(12) Patent Application Publication
(10) Pub. No.: US 2024/0321902 A1
(43) Pub. Date: Sep. 26, 2024

(54) CHIP-ON-FILM PACKAGE AND MANUFACTURING METHOD THEREOF

(71) Applicant: Samsung Electronics Co., Ltd., Suwon-si (KR)

(72) Inventors: Narae Shin, Suwon-si (KR); Jeongkyu Ha, Suwon-si (KR); Woonbae Kim, Suwon-si (KR); Yechung Chung, Suwon-si (KR); Jaemin Jung, Suwon-si (KR)

(21) Appl. No.: 18/612,828

(22) Filed: Mar. 21, 2024

(30) Foreign Application Priority Data
Mar. 24, 2023 (KR) 10-2023-0039016
May 31, 2023 (KR) 10-2023-0070410
Oct. 24, 2023 (KR) 10-2023-0143170

(51) Int. Cl. H01L 27/12

(52) U.S. Cl. CPC H01L 27/124

(57) ABSTRACT

A chip of film package comprises a film substrate having a chip mounting region, an inner lead bonding region arranged within the chip mounting region, and an outer lead bonding region spaced apart from the inner lead bonding region in a first direction, and providing upper and lower surfaces opposite to each other, a first upper wiring pattern arranged on the upper surface of the film substrate and extending in the first direction from the inner lead bonding region to the outer lead bonding region, a second upper wiring pattern spaced apart from the first upper wiring pattern in the first direction, an upper solder resist layer covering an upper surface of the first upper wiring pattern; and a lower solder resist layer covering an upper surface of the lower wiring pattern.

### CROSS-REFERENCE TO RELATED APPLICATION

This application is based on and claims priority under 35 U.S.C. § 119 to Korean Patent Application No. 10-2023-0039016, filed on Mar. 24, 2023, Korean Patent Application No. 10-2023-0070410, filed on May 31, 2023, and Korean Patent Application No. 10-2023-0143170, filed on Oct. 24, 2023, in the Korean Intellectual Property Office, the disclosures of all of which are incorporated by reference herein in their entireties.

### BACKGROUND

The inventive concept relates to a chip-on-film package, and more specifically, to a chip-on-film package including redistribution vias.

According to the trend of size reduction and weight reduction of electronic products, a chip-on-film (COF) package may be provided as a high-density semiconductor chip mounting technology. The COF package may include a semiconductor chip bonded to a substrate through flip-chip bonding, and redistribution patterns connected to the semiconductor chip and densely arranged on the substrate. Also, a substrate for manufacturing a chip-on-film package may include a test region for testing signal transfer characteristics of a semiconductor chip.

### SUMMARY

The inventive concept provides a chip-on-film package in which a width of an input region connected to a printed circuit board is reduced and which is finely manufactured.

The inventive concept provides a method of manufacturing a finer chip-on-film package by reducing a width of an input region connected to a printed circuit board.

According to an aspect of the inventive concept, a chip of film package includes a film substrate having a chip mounting region, an inner lead bonding region arranged within the chip mounting region, and an outer lead bonding region spaced apart from the inner lead bonding region in a first direction, and providing upper and lower surfaces opposite to each other, a first upper wiring pattern arranged on the upper surface of the film substrate and extending in the first direction from the inner lead bonding region to the outer lead bonding region, a second upper wiring pattern spaced apart from the first upper wiring pattern in the first direction, a first wiring via connected to the first upper wiring pattern, penetrating the film substrate, and extending toward the lower surface of the film substrate, a lower wiring pattern connected to the first wiring via on the lower surface of the film substrate and extending in the first direction, a second wiring via connected to the second upper wiring pattern, penetrating the film substrate, extending toward a lower surface of the film substrate, and connected to the lower wiring pattern, an upper solder resist layer covering an upper surface of the first upper wiring pattern, and a lower solder resist layer covering an upper surface of the lower wiring pattern, wherein the upper surface of the second upper wiring pattern is exposed without being covered by the upper solder resist layer.

According to another aspect of the inventive concept, a chip-on-film package includes a film substrate having an input region, an output region, and a chip mounting region between the input region and the output region, and providing upper and lower surfaces opposite to each other, a plurality of first upper wiring patterns arranged on the upper surface of the film substrate and extending from the chip mounting region in a first direction to the input region, a plurality of second upper wiring patterns arranged apart from the plurality of first upper wiring patterns in the first direction, a plurality of third upper wiring patterns respectively arranged between a pair of first upper wiring patterns arranged adjacent to one another in a second direction perpendicular to the first direction among the plurality of first upper wiring patterns, and an upper solder resist layer covering upper surfaces of the plurality of first upper wiring patterns and upper surfaces of the plurality of third upper wiring patterns, wherein upper surfaces of the plurality of second upper wiring patterns are exposed without being covered by the upper solder resist layer.

According to another aspect of the inventive concept, a chip-on-film package includes a film substrate having a chip mounting region, an inner lead bonding region arranged within the chip mounting region, and an outer lead bonding region spaced apart from the inner lead bonding region in a first direction, and providing upper and lower surfaces opposite to each other, a plurality of first upper wiring patterns arranged on the upper surface of the film substrate, overlapping the inner lead bonding region, extending in the first direction, and overlapping the outer lead bonding region, a plurality of second upper wiring patterns spaced apart from each of the plurality of first upper wiring patterns in the first direction and in a second direction perpendicular to the first direction, a first wiring via connected to each of the plurality of first upper wiring patterns, penetrating the film substrate, and extending toward the lower surface of the film substrate, a lower wiring pattern connected to the first wiring via on the lower surface of the film substrate and extending in the first direction, a second wiring via connected to each of the plurality of second upper wiring patterns, penetrating the film substrate, extending toward a lower surface of the film substrate, and connected to the lower wiring pattern, a plurality of third upper wiring patterns respectively arranged between a pair of first upper wiring patterns arranged adjacent in a second direction perpendicular to the first direction among the plurality of first upper wiring patterns, an upper solder resist layer covering upper surfaces of the plurality of first upper wiring patterns, and a lower solder resist layer covering an upper surface of the lower wiring pattern, wherein upper surfaces of the plurality of second upper wiring patterns are exposed without being covered by the upper solder resist layer.third upper wiring pattern

### BRIEF DESCRIPTION OF THE DRAWINGS

Embodiments will be more clearly understood from the following detailed description taken in conjunction with the accompanying drawings in which:

FIG. 1 is a perspective view of a chip-on-film package according to an example embodiment;

FIG. 2 is a cross-sectional view taken along line P-P′ of FIG. 1;

FIG. 3 is a plan view of the chip-on-film package illustrated in FIG. 1;

FIG. 4 is an enlarged view of a region A of FIG. 3;

FIG. 5 is a cross-sectional view taken along line Q-Q′ of FIG. 4;

FIG. 6 is a cross-sectional view taken along line R-R′ of FIG. 4;

FIG. 7 is an enlarged cross-sectional view of a first wiring structure illustrated in FIG. 5;

FIG. 8 is an enlarged cross-sectional view of a second wiring structure illustrated in FIG. 5;

FIG. 9 is a plan view of a chip-on-film package according to another example embodiment;

FIG. 10 is an enlarged view of a region B of FIG. 9;

FIG. 11 is a cross-sectional view of a chip-on-film package according to another example embodiment;

FIGS. 12 to 17 are cross-sectional views sequentially illustrating a method of manufacturing a chip-on-film package according to an example embodiment; and

FIG. 18 is a perspective view of a display device to which a chip-on-film package is attached according to an example embodiment.

### DETAILED DESCRIPTION OF THE EMBODIMENTS

Hereinafter, embodiments are described in detail with reference to the accompanying drawings. However, the inventive concept does not have to be configured as limited to the embodiments described below and may be embodied in various other forms. The following examples are provided to convey the scope of the inventive concept to those skilled in the art to which the inventive concept belongs. Like reference characters refer to like elements throughout.

Spatially relative terms, such as “beneath,” “below,” “lower,” “above,” “cupper” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 180 degrees or at other orientations) and the spatially relative descriptors used herein interpreted accordingly.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

It will be understood that, although the terms first, second, third etc. may be used herein to describe various elements, components, regions, layers and/or sections, these elements, components, regions, layers and/or sections should not be limited by these terms. Unless the context indicates otherwise, these terms are only used to distinguish one element, component, region, layer or section from another element, component, region, layer or section, for example as a naming convention. Thus, a first element, component, region, layer or section discussed below in one section of the specification could be termed a second element, component, region, layer or section in another section of the specification or in the claims without departing from the teachings of the present invention. In addition, in certain cases, even if a term is not described using “first,” “second,” etc., in the specification, it may still be referred to as “first” or “second” in a claim in order to distinguish different claimed elements from each other.

Terms such as “same,” “equal,” “planar,” or “coplanar,” as used herein when referring to orientation, layout, location, shapes, sizes, amounts, or other measures do not necessarily mean an exactly identical orientation, layout, location, shape, size, amount, or other measure, but are intended to encompass nearly identical orientation, layout, location, shapes, sizes, amounts, or other measures within acceptable variations that may occur, for example, due to manufacturing processes. The term “substantially” may be used herein to emphasize this meaning, unless the context or other statements indicate otherwise. For example, items described as “substantially the same,” “substantially equal,” or “substantially planar,” may be exactly the same, equal, or planar, or may be the same, equal, or planar within acceptable variations that may occur, for example, due to manufacturing processes.

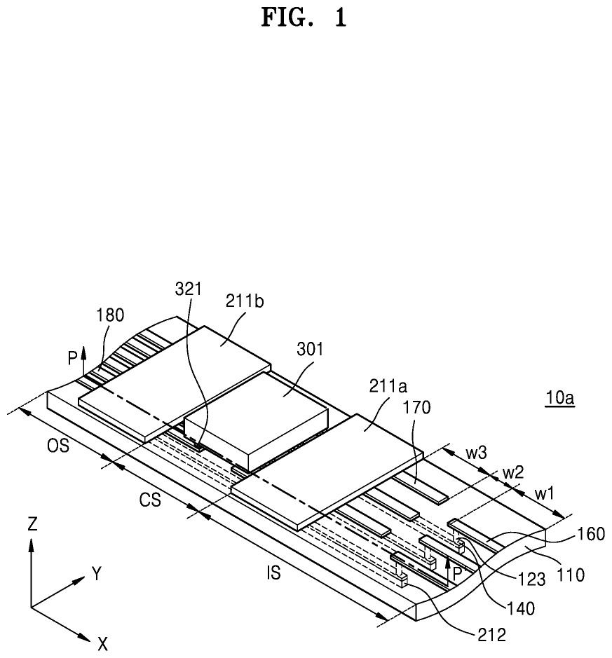

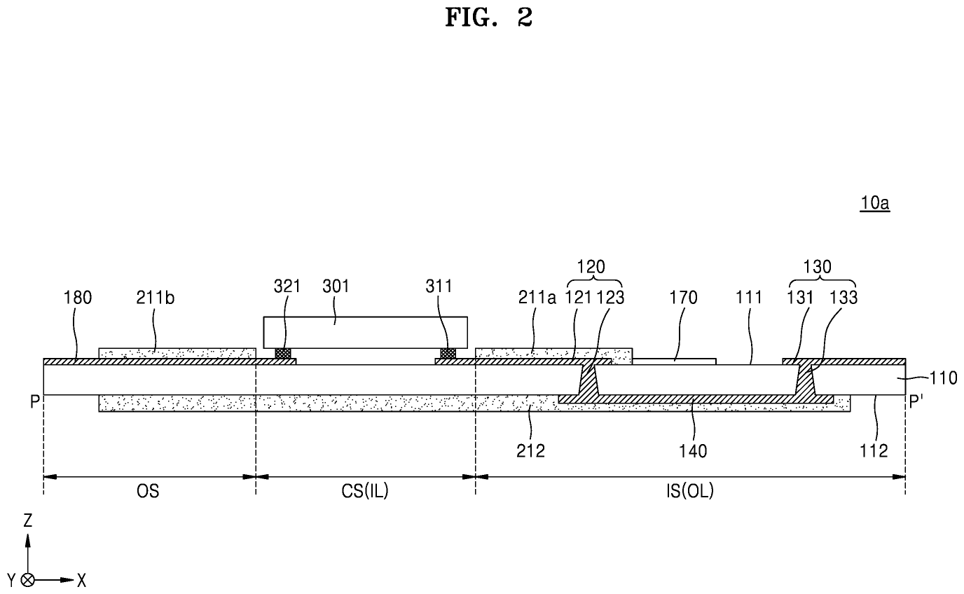

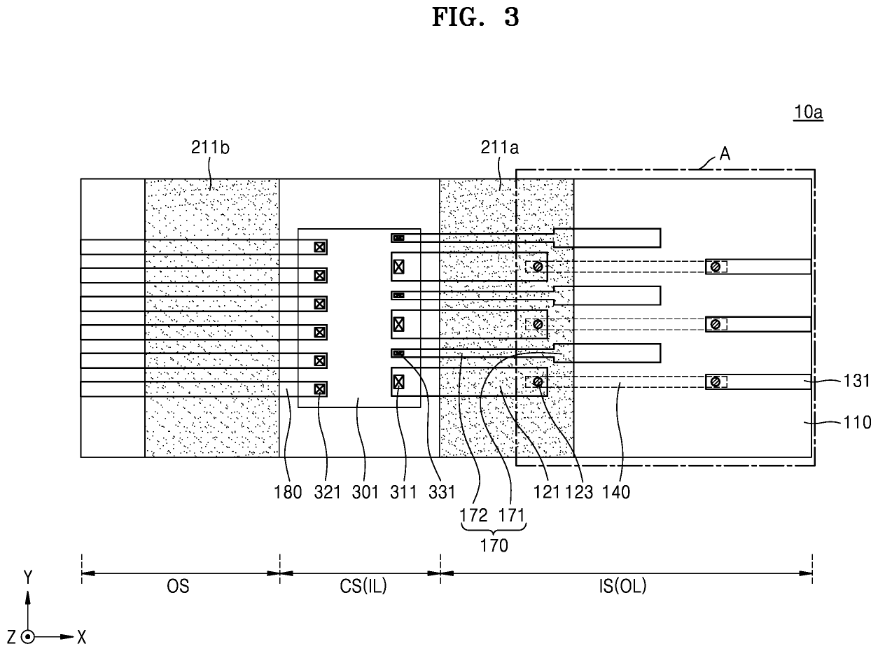

FIG. 1 is a perspective view of a chip-on-film package 10a according to an example embodiment, and FIG. 2 is a cross-sectional view taken along line P-P′ of FIG. 1. FIG. 3 is a plan view of the chip-on-film package 10a illustrated in FIG. 1.

The chip-on-film package 10a according to the inventive concept may be configured to mount a semiconductor chip 301 thereon.

Referring to FIGS. 1 to 3, the chip-on-film package 10a according to the embodiment may include a film substrate 110, a first wiring structure 120, a second wiring structure 130, a lower wiring pattern 140, a third upper wiring pattern 170, a fourth upper wiring pattern 180, first and second upper solder resist layers 211a and 211b and a lower solder resist layer 212, and the semiconductor chip 301.

The film substrate 110 of the chip-on-film package 10a may be a film for mounting the semiconductor chip 301 thereon. In one embodiment, the film substrate 110 may include an insulating material. For example, the film substrate 110 may be formed of or include a material, such as polyimide or an epoxy-based resin. In addition, the film substrate 110 may be a flexible film with flexibility.

In one embodiment, the film substrate 110 may have an upper surface 111 and a lower surface 112. The upper surface 111 of the film substrate 110 may be one surface of the film substrate 110 on which the semiconductor chip 301 is mounted. In addition, the lower surface 112 of the film substrate 110 may be the other surface of the film substrate 110 opposite to the upper surface 111.

Referring to FIGS. 1 and 2, a first direction (the X direction) and a second direction (the Y direction) may cross each other in the horizontal direction on the upper surface 111 of the film substrate 110. For example, the first direction (the X direction) may be perpendicular to the second direction (the Y direction). A third direction (the Z direction) may cross both the first direction (the X direction) and the second direction (the Y direction). For example, the third direction (the Z direction) may be perpendicular to the first direction (the X direction) and the second direction (the Y direction). Accordingly, the first direction (the X direction), the second direction (the Y direction), and the third direction (the Z direction) may be orthogonal to each other.

In the present specification, the first direction (the X direction) may be a direction in which the first upper wiring pattern 121 of the first wiring structure 120 is elongated. The third direction (Z direction) may be defined as a vertical direction, and may be a direction orthogonal to the upper surface of the film substrate 110.

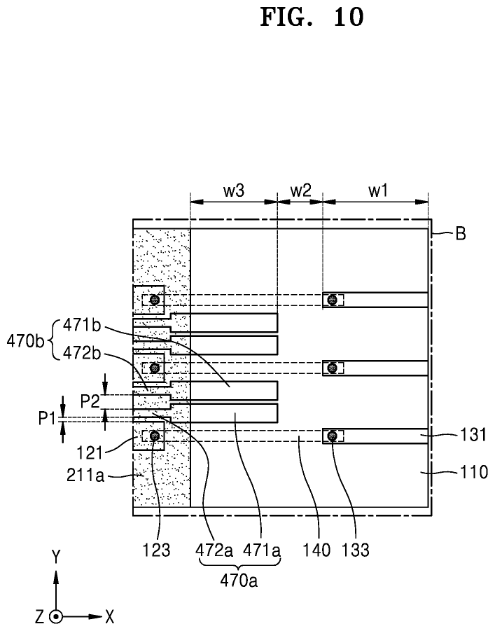

In one embodiment, the film substrate 110 may include a chip mounting region CS, an input region IS, an output region OS, and a test region TS. The chip mounting region CS may be one region of the film substrate 110 on which the semiconductor chip 301 is mounted. For example, the chip mounting region CS may be formed in a central portion of the film substrate 110. In addition, the film substrate 110 may optionally further include the test region TS (hereinafter, refer to FIGS. 10 to 15), and the test region TS may be optionally removed in an individualization process of the film substrate 110.

In the chip mounting region CS, an inner lead bonding region IL may be arranged. The inner lead bonding region IL may be defined as a region where the first upper wiring pattern 121, which may be an example of a lead frame, is bonded to the semiconductor chip 301.

The input region IS may be on one side of the chip mounting region CS and may be one region of the film substrate 110 for signal input. For example, the input region IS of the film substrate 110 may be one region of the film substrate 110 that is connected to a printed circuit board (PCB) and receives signals from the PCB.

An outer lead bonding region OL may be arranged in the input region IS. The outer lead bonding region OL may be defined as a region where the first upper wiring pattern 121, which may be an example of a lead frame, is bonded to another lead frame (for example, the lower wiring pattern 140).

The output region OS may be on the other side of the chip mounting region CS and may be one region of the film substrate 110 for signal output. For example, the chip mounting region CS may be between the output region OS and the input region IS. In example embodiments, the output region OS of the film substrate 110 may be one region of the film substrate 110 that is connected to a display panel and transmits signals to the display panel.

The solder resist layers 211a, 211b, and 212 may include the first upper solder resist layer 211a arranged in the input region IS on the upper surface 111 of the film substrate 110, and the second upper solder resist layer 211b arranged in the output region OS on the upper surface 111 of the film substrate 110. Also, the solder resist layers 211a, 211b, and 212 may include a lower solder resist layer 212 arranged on the lower surface 112 of the film substrate 110. As will be described in detail below, the first upper solder resist layer 211a may cover the top and side surfaces of the first upper wiring pattern 121, and the second upper solder resist layer 211b may cover the upper and side surfaces of the fourth upper wiring pattern 180. For example, the first upper solder resist layer 211a may contact the top and side surfaces of the first upper wiring pattern 121, and the second upper solder resist layer 211b may contact the upper and side surfaces of the fourth upper wiring pattern 180. Also, the lower solder resist layer 212 may cover upper and side surfaces of the lower wiring pattern 140. For example, the lower solder resist layer 212 may contact the upper and side surfaces of the lower wiring pattern 140. However, in some embodiments, the first upper wiring pattern 121 may not be covered by the first upper solder resist layer 211a and may be completely exposed.

The first wiring structure 120 of the chip-on-film package 10a may be in the input region IS of the film substrate 110. In one embodiment, the first wiring structure 120 may include a first upper wiring pattern 121 and a first wiring via 123.

The first wiring via 123 of the first wiring structure 120 may extend in the third direction (the Z direction) by penetrating a region between the upper surface 111 of the film substrate 110 and the lower surface 112 thereof. The first upper wiring pattern 121 of the first wiring structure 120 may be connected to the semiconductor chip 301 along the upper surface 111 of the film substrate 110 and may be elongated in the first direction (the X direction). For example, the first upper wiring pattern 121 may extend between the semiconductor chip 301 and the film substrate 110.

In one embodiment, the first wiring structure 120 may be formed of or include a metal, such as copper (Cu), nickel (Ni), aluminum (Al), gold (Au), silver (Ag), tungsten (W), or titanium (Ti), tantalum (Ta), indium (In), molybdenum (Mo), manganese (Mn), cobalt (Co), tin (Sn), magnesium (Mg), rhenium (Re), beryllium (Be), gallium (Ga), or ruthenium (Ru), or may include an alloy thereof.

In one embodiment, the first upper wiring pattern 121 may be a metal pad or an alloy pad extending in the horizontal direction on the upper surface 111 of the film substrate 110. For example, the first upper wiring pattern 121 may be in the input region IS of the film substrate 110. Also, the first upper wiring pattern 121 may be connected to the semiconductor chip 301 and may be arranged in both the chip mounting region CS and the input region IS of the film substrate 110.

In one embodiment, the lower wiring pattern 140 may be a metal pad or an alloy pad extending in the horizontal direction on the lower surface 112 of the film substrate 110. For example, the lower wiring pattern 140 may extend lengthwise in the first direction (the X direction) on the lower surface 112 of the film substrate 110. For example, the lower wiring pattern 140 may be in the input region IS of the film substrate 110. Also, the lower wiring pattern 140 may be electrically connected to the third upper wiring pattern 170, which is connected to the semiconductor chip 301 and is arranged in both the chip mounting region CS and the input region IS of the film substrate 110.

In one embodiment, the first wiring via 123 may connect the first upper wiring pattern 121 to the lower wiring pattern 140 by penetrating a region between the upper surface 111 and the lower surface 112 of the film substrate 110 in the third direction (the Z direction). For example, the first wiring via 123 may penetrate the input region IS of the film substrate 110 and connect the first upper wiring pattern 121 to the lower wiring pattern 140. In example embodiments, the first upper wiring pattern 121 may be a plurality of first upper wiring patterns 121, and a first wiring via 123 may be connected to each of the plurality of first upper wiring patterns 121.

In one embodiment, the first upper wiring pattern 121 of the chip-on-film package 10a may be on the upper surface 111 of the film substrate 110 and may be elongated in the first direction (the X direction). At least a part of the first upper wiring pattern 121 may overlap the semiconductor chip 301 in the third direction (the Z direction). The first upper wiring pattern 121 may cross the chip mounting region CS and the input region IS of the film substrate 110, and one end of the first upper wiring pattern 121 may be adjacent to the semiconductor chip 301, and the other end opposite to the one end may be adjacent to the first wiring via 123. The first upper wiring pattern 121 may provide an electrical path between the semiconductor chip 301 in the chip mounting region CS of the film substrate 110 and the lower wiring pattern 140 in the input region IS of the film substrate 110.

In one embodiment, the first upper wiring pattern 121 and the first wiring via 123 may be formed of or include a metal, such as copper (Cu), nickel (Ni), aluminum (Al), gold (Au), silver (Ag), tungsten (W), titanium (Ti)), tantalum (Ta), indium (In), molybdenum (Mo), manganese (Mn), cobalt (Co), tin (Sn), magnesium (Mg), rhenium (Re), beryllium (Be), gallium (Ga), or ruthenium (Ru), or an alloy thereof.

The chip-on-film package 10a may include the lower wiring pattern 140 that is on the lower surface 112 of the film substrate 110 and elongated in the first direction (the X direction). At least a part of the lower wiring pattern 140 may overlap the first upper wiring pattern 121 and a second upper wiring pattern 131 in the third direction (the Z direction). The lower wiring pattern 140 may be in the input region IS of the film substrate 110, and one end of the lower wiring pattern 140 may be adjacent to the first wiring structure 120, and the other end opposite to the one end may be adjacent to the second wiring structure 130. The lower wiring pattern 140 may provide an electrical path between the first wiring structure 120 and the second wiring structure 130 in the input region IS of the film substrate 110. Although FIG. 2 illustrates that the first wiring structure 120 and the lower wiring pattern 140 are integrally formed and connected to each other, the first wiring structure 120 and the lower wiring patterns 140 may be separated by forming an interface therebetween according to an embodiment and a manufacturing method.

In one embodiment, the lower wiring pattern 140 may be formed of or include a metal, such as copper (Cu), nickel (Ni), aluminum (Al), gold (Au), silver (Ag), tungsten (W), or titanium (Ti), tantalum (Ta), indium (In), molybdenum (Mo), manganese (Mn), cobalt (Co), tin (Sn), magnesium (Mg), rhenium (Re), beryllium (Be), gallium (Ga), or ruthenium (Ru), or an alloy thereof.

The second wiring structure 130 of the chip-on-film package 10a may be near an edge of the input region IS of the film substrate 110. For example, the second wiring structure 130 of the chip-on-film package 10a may be near the edge of the input region IS opposite to the edge adjacent to the chip region CS. In one embodiment, the second wiring structure 130 may include the second upper wiring pattern 131 and a second wiring via 133. As illustrated in FIG. 2 and FIG. 3, an upper surface of the second upper wiring pattern 131 is completely exposed without being covered by a solder resist layer or so on.

The second wiring via 133 of the second wiring structure 130 may extend in the third direction (the Z direction) by penetrating a region between the upper surface 111 and the lower surface 112 of the film substrate 110. The second wiring structure 130 may be connected to the lower wiring pattern 140 elongated in the first direction (the X direction) on the lower surface 112 of the film substrate 110. Although FIG. 2 illustrates that the second wiring structure 130 and the lower wiring pattern 140 are integrally formed and connected to each other, the second wiring structure 130 and the lower wiring patterns 140 may be separated from each other by forming an interface therebetween according to an embodiment and a manufacturing method.

In one embodiment, the second wiring structure 130 may be formed of or include a meatal, such as copper (Cu), nickel (Ni), aluminum (Al), gold (Au), silver (Ag), tungsten (W), titanium (Ti), tantalum (Ta), indium (In), molybdenum (Mo), manganese (Mn), cobalt (Co), tin (Sn), magnesium (Mg), rhenium (Re), beryllium (Be), gallium (Ga)), or ruthenium (Ru), or an alloy thereof.

In one embodiment, the second upper wiring pattern 131 may be a metal pad or an alloy pad extending in the horizontal direction on the upper surface 111 of the film substrate 110. For example, the second upper wiring pattern 131 may be near an edge of the input region IS of the film substrate 110.

According to one embodiment, the second upper wiring pattern 131 may be an input pad for a signal input of the chip-on-film package 10a. The second upper wiring pattern 131 may be connected to a part of a PCB, such as a flexible printed circuit board (FPCB), and receive electrical signals from the PCB.

In one embodiment, the second wiring via 133 may penetrate a region between the upper surface 111 and the lower surface 112 of the film substrate 110 in the third direction (the Z direction) to electrically and physically connect the second upper wiring pattern 131 to the lower wiring pattern 140. For example, the second wiring via 133 may penetrate the input region IS of the film substrate 110 to connect the second upper wiring pattern 131 to the lower wiring pattern 140. In example embodiments, the second wiring via 133 may extend between the second upper wiring pattern 131 and the lower wiring pattern 140. The second wiring via 133 may contact the lower wiring pattern 140. In example embodiments, the second upper wiring pattern 131 may be a plurality of second upper wiring patterns 131, and a second wiring via 133 may be connected to each of the plurality of second upper wiring patterns 131.

In one embodiment, the second upper wiring pattern 131 of the second wiring structure 130 may be on the upper surface 111 of the film substrate 110 and may be elongated in the first direction (the X direction). At least a part of the second upper wiring pattern 131 may overlap the lower wiring pattern 140 in the third direction (the Z direction). The second upper wiring pattern 131 may be in the input region IS of the film substrate 110. The second upper wiring pattern 131 may provide an electrical path between redistribution line patterns that may be in the test region TS (hereinafter, refer to FIGS. 10 to 15) to be removed in an individualization process of the chip-on-film package 10a. Also, the second upper wiring pattern 131 may be connected to a PCB that may be arranged in the input region IS.

A lower surface of the first upper wiring pattern 121 may be located at the same vertical level as a lower surface of the second upper wiring pattern 131. In example embodiments, the first upper wiring pattern 121 may be a plurality of first upper wiring patterns 121 and the second upper wiring pattern 131 may be a plurality of second upper wiring patterns 131. In such embodiments, a lower surface of each of the plurality of first upper wiring patterns 121 may be located at the same vertical level as a lower surface of each of the plurality of second upper wiring patterns 131. The plurality of first upper wiring patterns 121 may be spaced apart from the plurality of second upper wiring patterns 131 in the first and second directions (the X and Y directions).

In one embodiment, the second upper wiring pattern 131 may be formed of or include a metal, such as copper (Cu), nickel (Ni), aluminum (Al), gold (Au), silver (Ag), tungsten (W), or titanium (Ti), tantalum (Ta), indium (In), molybdenum (Mo), manganese (Mn), cobalt (Co), tin (Sn), magnesium (Mg), rhenium (Re), beryllium (Be), gallium (Ga), or ruthenium (Ru), or an alloy thereof.

In one embodiment, the third upper wiring pattern 170 of the chip-on-film package 10a may be on the upper surface 111 of the film substrate 110 and may be elongated in the first direction (the X direction). The third upper wiring pattern 170 may be between a plurality of first wiring structures 120 to be arranged apart from the plurality of first wiring structures 120 in the second direction (the Y direction). For example, each of the third upper wiring patterns 170 may be between a pair of first upper wiring patterns 121 adjacent in the second direction (the Y direction). At least a part of the third upper wiring pattern 170 may overlap the semiconductor chip 301 in the third direction (the Z direction). The third upper wiring pattern 170 may cross the chip mounting region CS and the input region IS of the film substrate 110, and one end of the third upper wiring pattern 170 may be adjacent to the semiconductor chip 301 in the chip mounting region CS, and the other end opposite to the one end may be in the input region IS. The third upper wiring pattern 170 may be physically and electrically connected to a PCB that may be arranged in the input region IS, and provide an electrical connection path between the semiconductor chip 301 and the PCB.

The third upper wiring pattern 170 may include a first region 171 having a relatively wide width in the second direction (the Y direction) and a second region 172 having a relatively narrow width in the second direction (the Y direction). For example, a width of the first region 171 in the second direction (the Y direction) may be greater than a width of the second region 172 in the second direction (the Y direction). In example embodiments, the width of the second region 172 in the second direction (the Y direction) may be smaller than a width of the first upper wiring pattern 121 in the second direction (the Y direction). In this case, the first region 171 may be in the input region IS of the film substrate 110 and may be connected to a PCB that may be arranged in the input region IS. In addition, the second region 172 may be arranged in both the chip mounting region CS and the input region IS, and a partial region of the second region 172 that is not covered by the first upper solder resist layer 211a may overlap the semiconductor chip 301 in the third direction (the Z direction). Although FIG. 3 illustrates that a length of the second region 172 in the first direction (the X direction) is longer than a length of the first region 171 in the first direction (the X direction), the length of the first region 171 in the first direction (the X direction) may be longer than the length of the second region 172 in the first direction (the X direction).

In one embodiment, the third upper wiring pattern 170 may be formed of or include a metal, such as copper (Cu), nickel (Ni), aluminum (Al), gold (Au), silver (Ag), tungsten (W), titanium (Ti), tantalum (Ta), indium (In), molybdenum (Mo), manganese (Mn), cobalt (Co), tin (Sn), magnesium (Mg), rhenium (Re), beryllium (Be), gallium (Ga), or ruthenium (Ru), or an alloy thereof.

The first and second upper solder resist layers 211a and 211b and the lower solder resist layer 212 of the chip-on-film package 10a may be conformally formed along the upper surface 111 and the lower surface 112 of the film substrate 110.

In one embodiment, the first upper solder resist layer 211a may cover a part of the first upper wiring pattern 121 and a part of the third upper wiring pattern 170 on the upper surface 111 of the film substrate 110. In this case, the first upper solder resist layer 211a may be in the input region IS of the film substrate 110. also, the first upper solder resist layer 211a may expose a part of the first upper wiring pattern 121 such that the first upper wiring pattern 121 may be connected to the semiconductor chip 301 with a first chip connection terminal 311 therebetween. The first upper solder resist layer 211a may expose a part of the third upper wiring pattern 170 such that the first region 171 of the third upper wiring pattern 170 may be connected to a PCB to be placed in the input region IS.

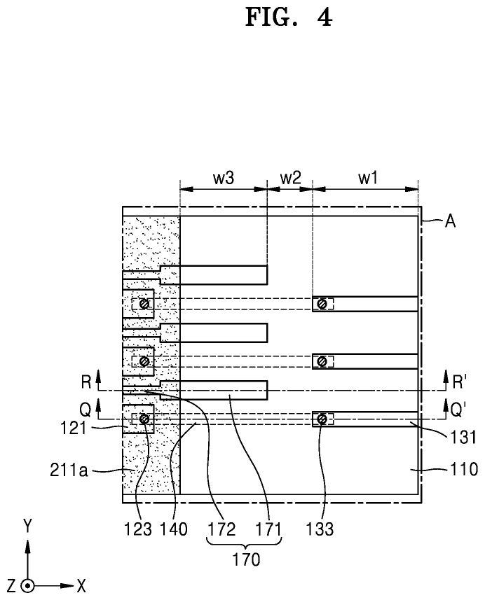

As discussed further below in connection with FIG. 4, a width w1 of the second upper wiring pattern 131 in the first direction (the X direction) may be about 500 micrometers to about 1000 micrometers, a separation distance w2 between the second upper wiring pattern 131 and the third upper wiring pattern 170 in the first direction (the X direction) may be about 100 micrometers to about 300 micrometers, and a width w3 of a region of the third upper wiring pattern 170 not covered by the first upper solder resist layer.

In one embodiment, the second upper solder resist layer 211b may cover a part of the fourth upper wiring pattern 180 on the upper surface 111 of the film substrate 110. For example, the second upper solder resist layer 211b may contact part of the fourth upper wiring pattern 180 on the upper surface 111 of the film substrate 110. In this case, the second upper solder resist layer 211b may be in the output region OS of the film substrate 110. Also, the second upper solder resist layer 211b may expose a part of the fourth upper wiring pattern 180 such that the fourth upper wiring pattern 180 may be connected to the semiconductor chip 301 with a second chip connection terminal 321 therebetween. For example, the second chip connection terminal 321 may contact an upper surface of the fourth upper wiring pattern 180 and a lower surface of the semiconductor chip 301. The second upper solder resist layer 211b may expose a part of the fourth upper wiring pattern 180 such that the fourth upper wiring pattern 180 may be connected to a display panel to be placed in the output region OS.

In one embodiment, the lower solder resist layer 212 may cover the lower wiring pattern 140 on the lower surface 112 of the film substrate 110. In this case, the lower solder resist layer 212 may be arranged in the output region OS, the chip mounting region CS, and the input region IS of the film substrate 110.

In one embodiment, the first and second upper solder resist layers 211a and 211b and the lower solder resist layer 212 may include insulating materials. For example, the first and second upper solder resist layers 211a and 211b and the lower solder resist layer 212 may be formed of or include silicon nitride (SiN), silicon oxynitride (SiON), silicon oxide (SiO₂), silicon carbonate nitride (SiOCN), and silicon carbonitride (SiCN), or a combination thereof.

The chip-on-film package 10a may include the first and second chip connection terminals 311 and 321 on the upper surface 111 of the film substrate 110. The first chip connection terminal 311 may be closer to the input region IS than the second chip connection terminal 321, and the second chip connection terminal 321 may be closer to the output region OS than the first chip connection terminal 311. The semiconductor chip 301 may be flip-chip-bonded onto the film substrate 110 through the first and second chip connection terminals 311 and 321. According to one embodiment, the first and second chip connection terminals 311 and 321 may be bumps. The first and second chip connection terminals 311 and 321 may be formed of or include tin (Sn), lead (Pb), copper (Cu), aluminum (Al), gold (Au), silver (Ag), titanium (Ti), or tungsten (W), or a conductive material including a combination thereof.

In some embodiments, the semiconductor chip 301 mounted on the upper surface 111 of the film substrate 110 may be a display driver integrated circuit (DDI) chip. The semiconductor chip 301 may operate and control pixels of a display panel. The semiconductor chip 301 may include a gate drive integrated circuit for driving gate lines and/or a data drive integrated circuit for driving data lines. In some embodiments, the semiconductor chip 301 may further include a timing controller, graphic RAM (GRAM), and a power driver in addition to the display driver integrated circuit.

As illustrated in FIGS. 1 to 3, the second wiring vias 133 of the second wiring structure 130 does not vertically overlap a solder resist layer or so on. For example, the second upper wiring pattern 131 of the second wiring structure 130 is completely exposed, and an upper surface of the second wiring structure 130 is not covered by an insulating material, such as a solder resist layer. Subsequently, as can be seen in detail from FIGS. 10 to 15, the film substrate 110 may optionally include a test region for testing signal transfer characteristics of the semiconductor chip 301, and in this case, a part of a solder resist layer and a part of the second upper wiring pattern 131 in a test region are removed in an individualization process of the film substrate 110. The second wiring via 133 is close to the first upper wiring pattern 121 in the first direction (the X direction) in the input region IS without vertically overlapping a solder resist layer or so on. Accordingly, the second upper wiring pattern 131 may be largely removed in the range where the second wiring via 133 is not removed in an individualization process of the film substrate 110, and a size of the chip-on-film package 10a may be further reduced.

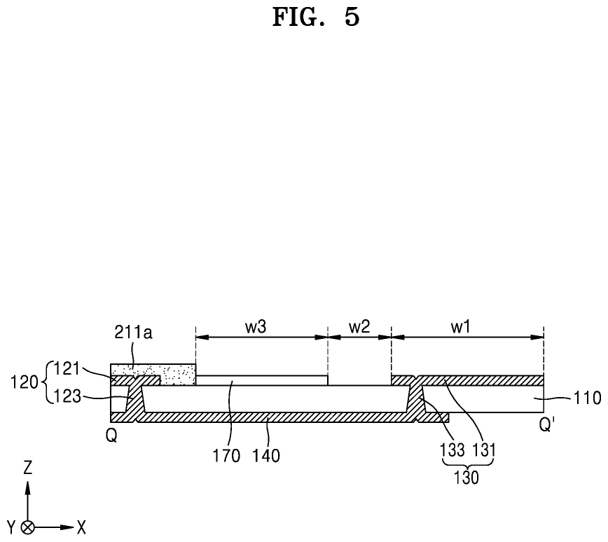

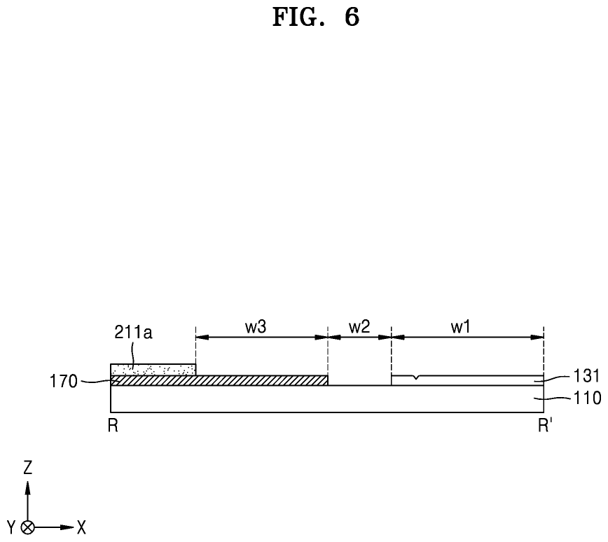

FIG. 4 is an enlarged view of a region A of FIG. 3. In addition, FIG. 5 is a cross-sectional view taken along line Q-Q′ of FIG. 4, and FIG. 6 is a cross-sectional view taken along line R-R′ of FIG. 4.

Referring to FIGS. 4 to 6, the first upper wiring pattern 121 and the second upper wiring pattern 131 may be arranged apart from each other in the first direction (the X direction) on the upper surface 111 of the film substrate 110. Also, the first upper wiring pattern 121 and the third upper wiring pattern 170 may be arranged apart from each other in the second direction (the Y direction) on the upper surface 111 of the film substrate 110. A width w1 of the second upper wiring pattern 131 in the first direction (the X direction) may be about 500 micrometers to about 1000 micrometers. Also, a separation distance w2 between the second upper wiring pattern 131 and the third upper wiring pattern 170 in the first direction (the X direction) may be about 100 micrometers to about 300 micrometers. A width w3 of a region of the third upper wiring pattern 170 not covered by the first upper solder resist layer 211a in the first direction (the X direction) may be about 700 micrometers to 1300 micrometers.

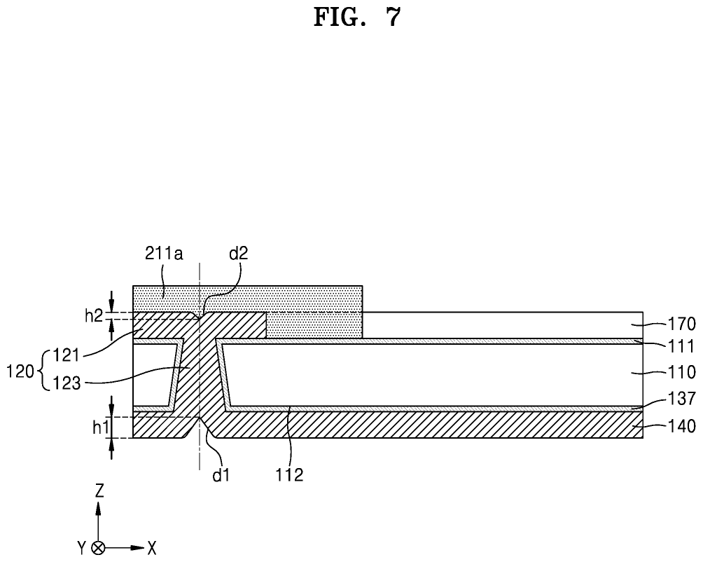

FIG. 7 is an enlarged cross-sectional view of the first wiring structure 120 illustrated in FIG. 5.

Referring to FIG. 7, a seed layer 137 may be conformally formed on the upper and lower surfaces 111 and 112 of the film substrate 110 and a surface of the first wiring via 123. For example, the seed layer 137 may be conformally formed on a side surface of the film substrate to be in contact with the surface of the first wiring via 123. The seed layer 137 may be formed of or include copper (Cu), chrome-copper (Cr-Cu), palladium (Pd), platinum (Pt), gold (Au), or a combination thereof.

The first wiring via 123 of the first wiring structure 120 may have a diameter that gradually reduces from the lower surface 112 toward the upper surface 111 of the film substrate 110. This is because the first wiring via 123 is formed by filling a hole of the film substrate 110 from the lower surface 112 to the upper surface 111 of the film substrate 110.

A first dimple d1 having a first depth h1 may be formed on a surface of the lower wiring pattern 140, and a second dimple d2 having a second depth h2 may be formed on a surface of the first upper wiring pattern 121. Each of the first dimple d1 and the second dimple d2 may be aligned on a central axis of the first wiring via 123. In this case, the first depth h1 may be greater than the second depth h2. When the second depth h2 of the second dimple d2 is formed deeper on the surface of the first upper wiring pattern 121, issues, such as a poor connection and an increase in resistance, may occur while the first upper wiring pattern 121 is connected to a PCB. Accordingly, by forming the first wiring via 123 from the lower surface 112 of the film substrate 110 toward the upper surface 111 thereof, the second depth h2 of the second dimple d2 may be formed shallower on the surface of the first upper wiring pattern 121.

In example embodiments, the first depth h1 of the first dimple d1 may be less than one-third of the thickness of the first upper wiring pattern 121. For example, the first depth h1 of the first dimple d1 may be about 25% of the thickness of the first upper wiring pattern 121 in the third direction (the Z direction). In example embodiments, the second depth h2 of the second dimple d2 may be greater than one-half of the thickness of the lower wiring pattern 140. For example, the second depth h2 of the second dimple d2 may be about 75% of the thickness of the lower wiring pattern 140 in the third direction (the Z direction).

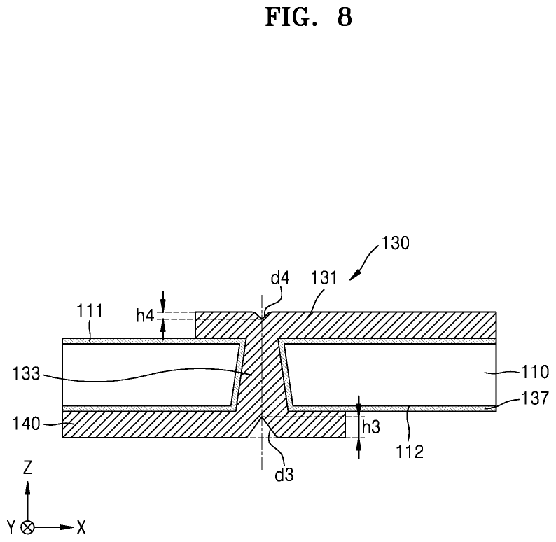

FIG. 8 is an enlarged cross-sectional view of the second wiring structure 130 illustrated in FIG. 5.

Referring to FIG. 8, the seed layer 137 may be conformally formed on the upper and lower surfaces 111 and 112 of the film substrate 110 and the surface of the second wiring via 133. For example, the seed layer 137 may be conformally formed on a side surface of the film substrate to be in contact with the surface of the second wiring via 133. The seed layer 137 may be formed of or include copper (Cu), chrome-copper (Cr-Cu), palladium (Pd), platinum (Pt), gold (Au), or a combination thereof.

The second wiring via 133 of the second wiring structure 130 may have a diameter that gradually reduces from the lower surface 112 of the film substrate 110 toward the upper surface 111 of the film substrate 110. This is because the second wiring via 133 is formed by filling a hole of the film substrate 110 from the lower surface 112 of the film substrate 110 to the upper surface 111 of the film substrate 110.

The third dimple d3 having the third depth h3 may be formed on a surface of the lower wiring pattern 140, and the fourth dimple d4 having the fourth depth h4 may be formed on a surface of the second upper wiring pattern 131. Each of the third dimple d3 and the fourth dimple d4 may be aligned on a central axis of the second wiring via 133. In this case, the third depth h3 may be greater than the fourth depth h4. When the fourth depth h4 of the fourth dimple d4 is formed deeper on a surface of the second upper wiring pattern 131, issues, such as a poor connection and an increase in resistance, may occur while the second upper wiring pattern 131 is connected to a PCB. Accordingly, by forming the second wiring via 133 from the lower surface 112 of the film substrate 110 toward the upper surface 111 thereof, the fourth depth h4 of the fourth dimple d4 may be formed shallower on the surface of the second upper wiring pattern 131.

In example embodiments, the third depth h3 of the third dimple d3 may be less than one-third of the thickness of the second upper wiring pattern 131. For example, the third depth h3 of the third dimple d3 may be about 25% of the thickness of the second upper wiring pattern 131 in the third direction (the Z direction). In example embodiments, the fourth depth h4 of the fourth dimple d42 may be greater than one-half of the thickness of the lower wiring pattern 140. For example, the fourth depth h4 of the fourth dimple d4 may be about 75% of the thickness of the lower wiring pattern 140 in the third direction (the Z direction).

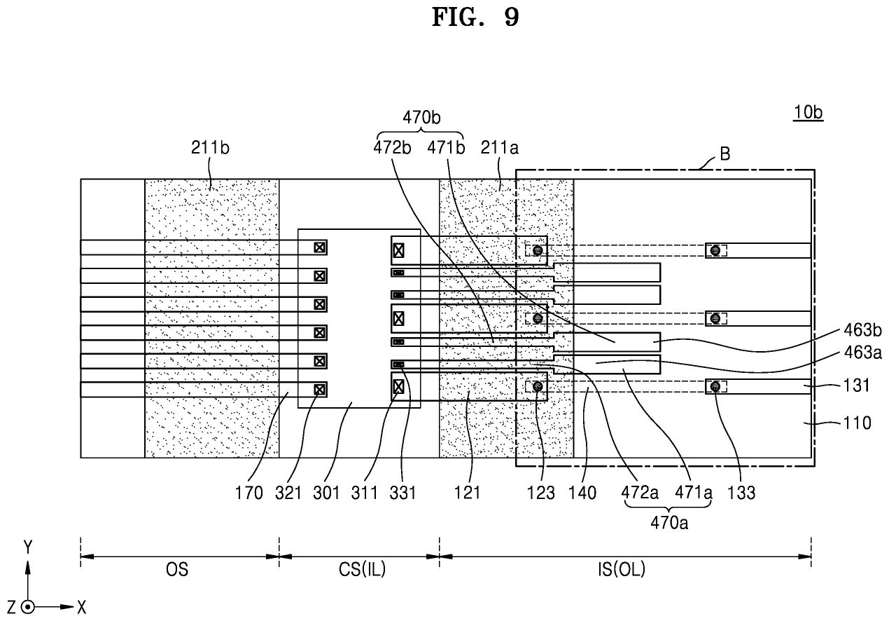

FIG. 9 is a plan view of a chip-on-film package according to another example embodiment, and FIG. 10 is an enlarged view of a region B of FIG. 9. When a chip-on-film package 10b illustrated in FIGS. 9 and 10 is compared with the chip-on-film package 10a illustrated in FIGS. 1 to 8, the chip-on-film package 10b is substantially the same as or similar to the chip-on-film package 10a except that arrangements of third upper redistribution line patterns 470a and 470b are different from arrangement of the third upper wiring pattern 170. Accordingly, descriptions of components previously given with reference to FIGS. 1 to 3 are not repeated.

Referring to FIGS. 9 and 10, a plurality of the third upper redistribution line patterns 470a and 470b may be between a plurality of the first upper wiring patterns 121 in the second direction (the Y direction). For example, two third upper redistribution line patterns 470a and 470b may be between a pair of the first upper wiring patterns 121 adjacent in the second direction (the Y direction). Although FIGS. 9 and 10 illustrate that two third upper redistribution line patterns 470a and 470b are between the plurality of first upper wiring patterns 121, there may be three or more third upper redistribution line patterns 470a and 470b therebetween depending on embodiments. The third upper redistribution line patterns 470a and 470b may respectively include first regions 471a and 471b that are relatively wide in the second direction (the Y direction) and second regions 472a and 472b that are relatively narrow in the second direction (the Y direction). For example, widths of the first regions 471a and 471b in the second direction (the Y direction) may be greater than widths of the second regions 472a and 472b in the second direction (the Y direction). In example embodiments, widths of the second regions 472a and 472b in the second direction (the Y direction) may be smaller than widths of the first upper wiring patterns 121 in the second direction (the Y direction). In this case, the first regions 471a and 471b of the third upper redistribution line patterns 470a and 470b may be respectively separated from the first upper wiring patterns 121 by a first pitch P1 in the second direction (Y direction), and the second regions 472a and 472b of the plurality of third upper redistribution line patterns 470a and 470b adjacent to each other may be separated from each other by a second pitch P2 in the second direction (Y direction). According to one embodiment, the second pitch P2 may be greater than the first pitch P1.

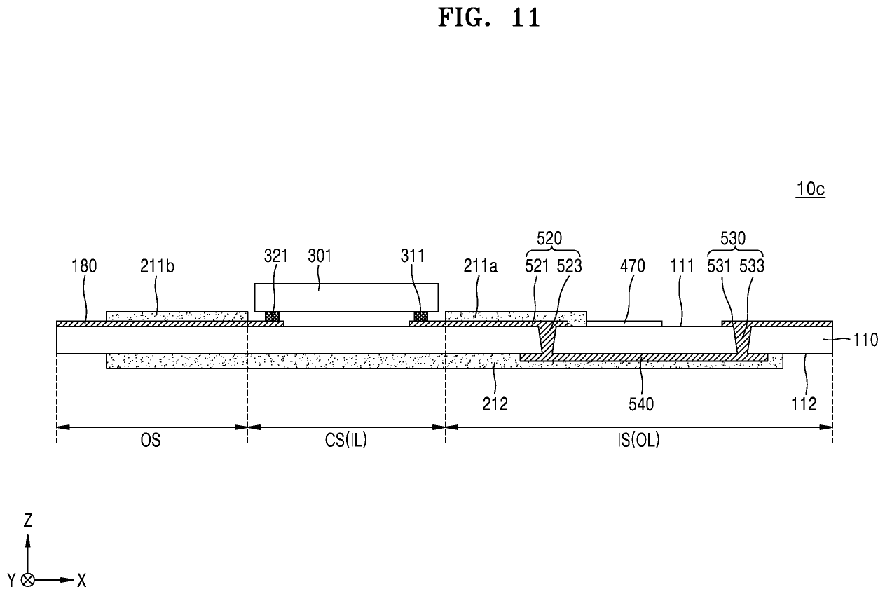

FIG. 11 is a cross-sectional view of a chip-on-film package 10c according to another example embodiment. When the chip-on-film package 10c illustrated in FIG. 11 is compared with the chip-on-film package 10a illustrated in FIGS. 1 to 8, the chip-on-film package 10c is substantially the same as or similar to the chip-on-film package 10a except that shapes of a first wiring via 523 and a second wiring via 533 are different from shapes of the first wiring via 123 and the second wiring via 133, respectively. Therefore, descriptions of components previously given with reference to FIGS. 1 to 8 are not repeated.

Referring to FIG. 11, a first wiring structure 520 may include a first upper wiring pattern 521 elongated on the upper surface 111 of the film substrate 110 and the first wiring via 523 that is integrally formed with the first upper wiring pattern 521 and penetrates the film substrate 110. Also, a second wiring structure 530 may include a second upper wiring pattern 531 elongated on the upper surface 111 of the film substrate 110 and the second wiring via 533 that is integrally formed with the second upper wiring pattern 531 and penetrates the film substrate 110. The first upper wiring pattern 521 and the second upper wiring pattern 531 are substantially the same as the first upper wiring pattern 121 and the second upper wiring pattern 131, respectively, of FIGS. 1 to 8.

The first wiring via 523 of the first wiring structure 520 may have a diameter that gradually reduces from the upper surface 111 of the film substrate 110 toward the lower surface 112 of the film substrate 110. Also, the second wiring via 533 of the second wiring structure 530 may have a diameter that gradually reduces from the upper surface 111 of the film substrate 110 toward the lower surface 112 of the film substrate 110. This is because the first wiring via 523 and the second wiring via 533 are formed by filling holes of the film substrate 110 from the upper surface 111 of the film substrate 110 to the lower surface 112 of the film substrate 110.

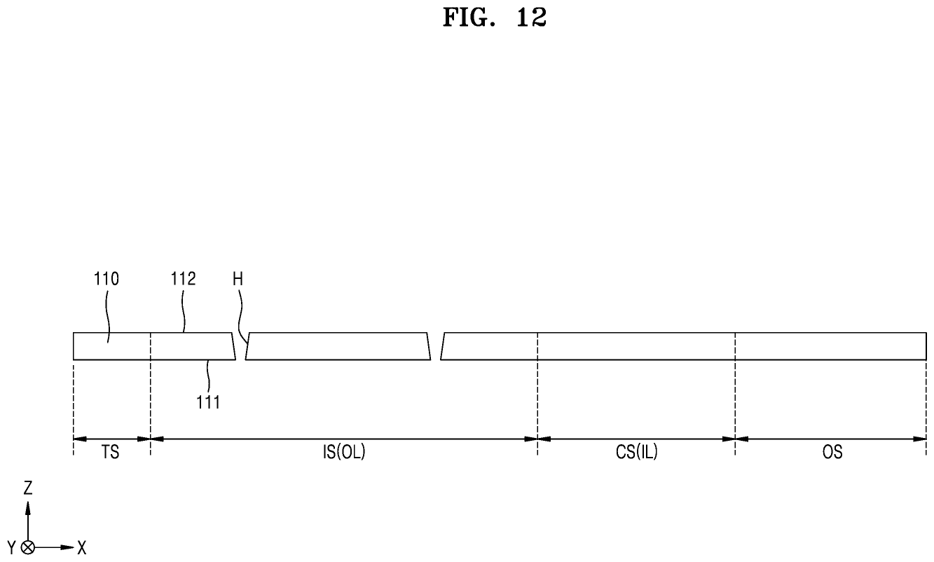

FIGS. 12 to 17 are cross-sectional views sequentially illustrating a method of manufacturing the chip-on-film package 10a, according to an example embodiment.

Referring to FIG. 12, a method of manufacturing a chip-on-film package, according to an example embodiment may first include forming via holes H in the film substrate 110. For example, the via holes H may be formed in the input region IS of the film substrate 110 of the film substrate 110. Thereafter, the via holes H of the film substrate 110 may each be filled with a conductive material to form a redistribution pattern. In one embodiment, the via holes H may be formed by vertically penetrating the film substrate 110 through a laser drilling process or an etching process. For example, the via holes H may be formed in a direction from a lower surface 112 of the film substrate 110 to an upper surface 111 of the film substrate 110.

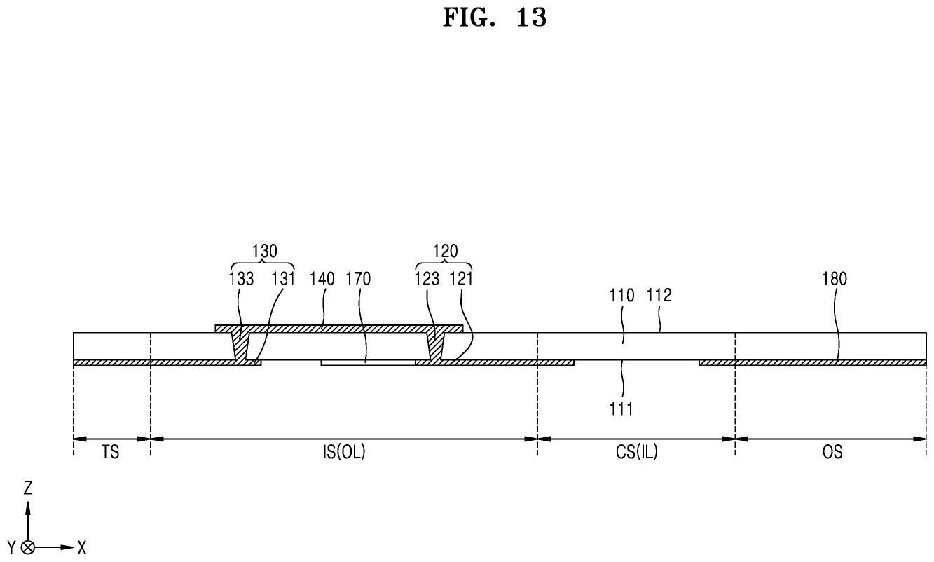

Referring to FIG. 13, in the method of manufacturing the chip-on-film package, according to an example embodiment, the first wiring structure 120, the second wiring structure 130, the third upper wiring pattern 170, and the fourth upper wiring pattern 180 may be formed on the upper surface 111 and the lower surface 112 of a film substrate 110 through a photolithography process, a plating process, an etching process, and so on.

In one embodiment, an operation of forming the first wiring structure 120 and the second wiring structure 130 may include an operation of filling the via holes H of the film substrate 110 with a conductive material. Then, an operation of forming the third upper wiring pattern 170 and the fourth upper wiring pattern 180 on the upper surface 111 of the film substrate 110 may be provided.

In one embodiment, an operation of forming the lower wiring pattern 140 that connects the first wiring via 123 of the first wiring structure 120 to the second wiring vias 133 of the second wiring structure 130 in the output region OS of the film substrate 110 may be provided.

In one embodiment, an operation of forming the first upper wiring pattern 121 that is connected to the first wiring via 123 in both the input region IS and the chip mounting region CS of the film substrate 110 may be provided. In addition, an operation of forming the second upper wiring pattern 131 that is connected to the second wiring via 133 in both the input region IS and the test region TS of the film substrate 110 may be provided.

In one embodiment, an operation of forming the fourth upper wiring pattern 180 in both the chip mounting region CS and the input region IS on an upper surface of the film substrate 110 may be provided.

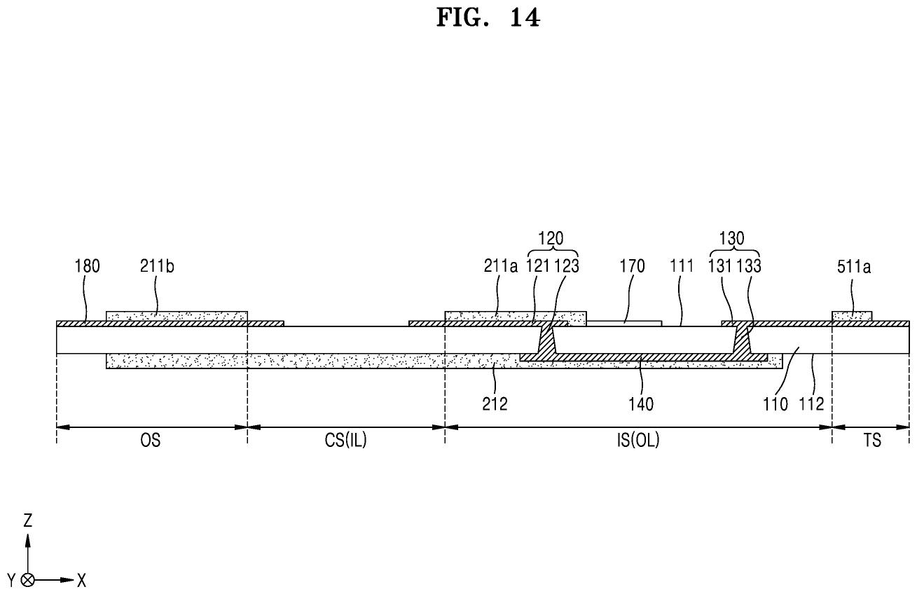

Referring to FIG. 14, a method of manufacturing a chip-on-film package, according to an example embodiment, may include an operation of forming the first and second upper solder resist layers 211a and 211b and the lower solder resist layer 212 on the upper surface 111 and the lower surface 112, respectively, of the film substrate 110 through a coating process, a photolithography process, and an etching process. Also, after the operation of forming the first wiring structure 120, the second wiring structure 130, the third upper wiring pattern 170, and the fourth upper wiring pattern 180 described with reference to FIG. 13, the film substrate 110 may be turned over to form the first and second upper solder resist layers 211a and 211b and the lower solder resist layer 212. For example, the film substrate 110 of FIG. 13 may be rotated 180 degrees to subsequently perform the operation of forming the first and second upper solder resist layers 211a and 211b and the lower solder resist layer 212 on the upper surface 111 and the lower surface 112, respectively.

In one embodiment, the first upper solder resist layer 211a may be formed to cover at least a part of the first upper wiring pattern 121 and at least a part of the third upper wiring pattern 170. Also, the second upper solder resist layer 211b may be formed to cover at least a part of the fourth upper wiring pattern 180.

In one embodiment, a third upper solder resist layer 511a may be formed to cover at least a part of an upper surface of the second upper wiring pattern 131 in the test region TS of the film substrate 110. Also, the lower solder resist layer 212 may be formed to cover the lower wiring pattern 140 on the lower surface 112 of the film substrate 110.

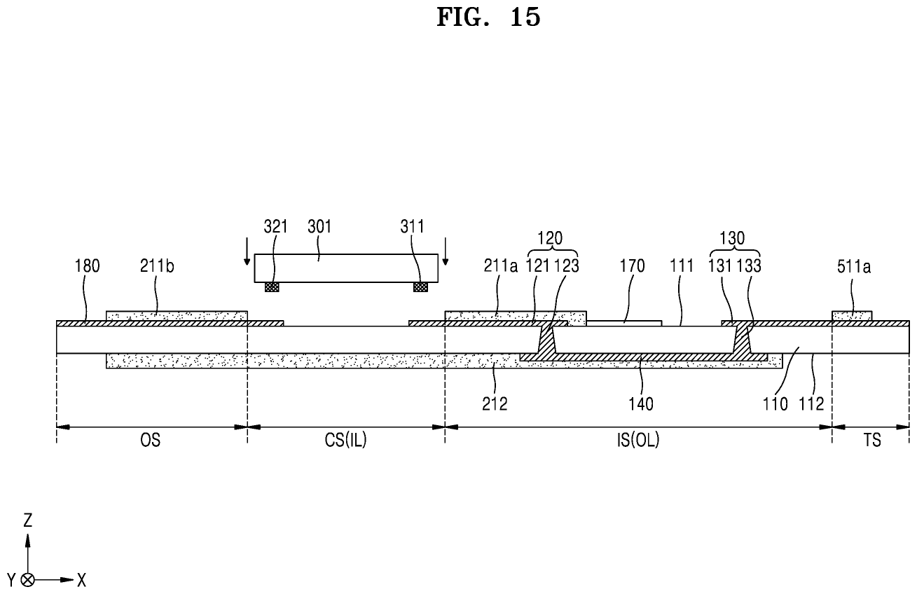

Referring to FIG. 15, a method of manufacturing a chip-on-film package, according to an example embodiment, may include an operation of mounting the semiconductor chip 301 on the chip mounting region CS of the film substrate 110 through flip chip bonding.

In one embodiment, the semiconductor chip 301 may be mounted on the chip mounting region CS of the film substrate 110 such that the first and second chip connection terminals 311 and 321 of the semiconductor chip 301 come into contact with the first upper wiring pattern 121 and the fourth upper wiring pattern 180 on the chip mounting region CS of the film substrate 110.

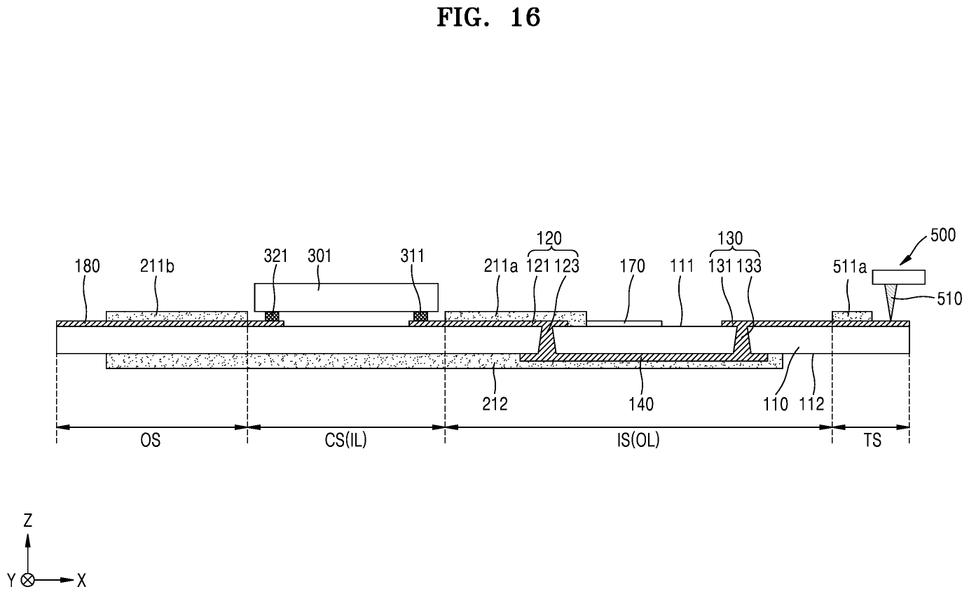

Referring to FIG. 16, a method of manufacturing a chip-on-film package, according to an example embodiment, may include an operation of testing an electrical signal flow of the chip-on-film package by using a test device 500.

In this case, the test device 500 including a test pin 510 may be used to test the electrical signal flow of the chip-on-film package 10a. For example, the test device 500 may include a probe card.

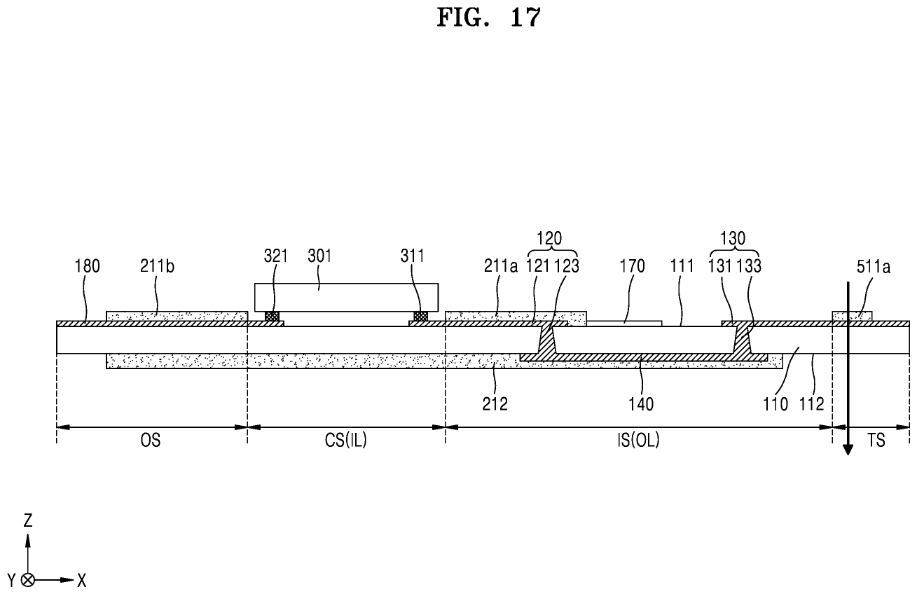

Referring to FIG. 17, a method of manufacturing a chip-on-film package, according to an example embodiment, may include an operation of cutting the test region TS of the film substrate 110 on which the semiconductor chip 301 is mounted. In this case, the operation of cutting the test region TS may be performed by using a blade wheel. However, the manufacturing method is not limited thereto and may also include an operation of cutting the test region TS by using a laser. A part of the second upper wiring pattern 131 and a part of the third upper solder resist layer 511a may be removed by the operation of cutting the test region TS of the film substrate 110.

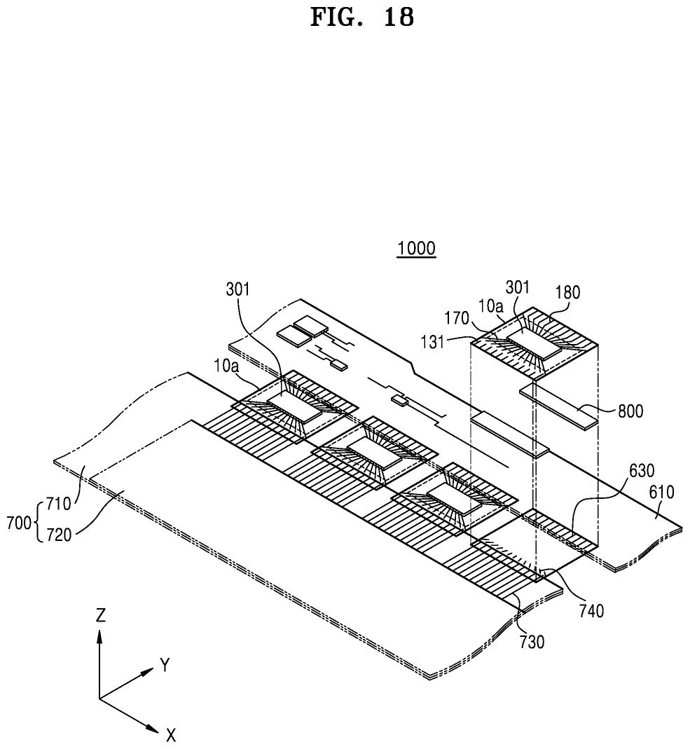

FIG. 18 is a perspective view of a display device to which a chip-on-film package is attached according to an example embodiment.

Referring to FIG. 18, the display device 1000 may include at least one chip-on-film package 10a, a driving printed circuit board 610, and a display panel 700.

The chip-on-film package 10a may be a package including a semiconductor chip 301 that is a display driver IC (DDI). In some embodiments, one semiconductor chip 301 may be arranged in one chip-on-film package 10a. In other embodiments, different types of semiconductor chips 301 may be arranged in one chip-on-film package 10a. For example, the semiconductor chip 301 may include a source driving chip and/or a gate driving chip.

The chip-on-film package 10a may be positioned between the driving printed circuit board 610 and the display panel 700 and connected to them respectively. The chip-on-film package 10a may receive a signal output from the driving printed circuit board 610 and transmit the signal to the display panel 700.

The chip-on-film package 10a may be electrically connected to a driving connection wire 630 of the driving printed circuit board 610 and a plurality of panel connection wires 730 and 740 of the display panel 700, respectively. The plurality of panel connection wires 730 and 740 include first panel connection wires 730 and second panel connection wires 740 spaced apart from the first panel connection wires 730 in the first direction (X direction) and second direction (Y direction). The second panel connection wires 740 may be arranged to cross each other. Specifically, the driving connection wiring 630 may be attached to and electrically connected to the fourth upper wiring pattern 180 of the chip-on-film package 10a. Also, the first panel connection wires 730 may be attached to and electrically connected to the second upper wiring pattern 131 of the chip-on-film package 10a. The second panel connection wires 740 may be attached to and electrically connected to the third upper wiring pattern 170 of the chip-on-film package 10a.

The display panel 700 may include a transparent substrate 710, an image region 720 formed on the transparent substrate 710, and a plurality of panel connection wires 730 and 740. The transparent substrate 710 may be, for example, a glass substrate or a flexible substrate. The plurality of pixels of the image region 720 may be connected to a plurality of corresponding panel connection wires 730 and 740 and operated according to signals provided by the semiconductor chip 301.

The chip-on-film package 10a may have an input pad formed at one end and an output pad formed at the other end. Each of the input pad and the output pad may be connected to the driving connection wire 630 and the plurality of panel connection wires 730 and 740 through an anisotropic conductive layer 800. The anisotropic conductive layer 800 may be, for example, an anisotropic conductive film or an anisotropic conductive paste. The anisotropic conductive layer 800 may have a structure in which conductive particles are dispersed in an insulating adhesive layer. In addition, the anisotropic conductive layer 800 may have anisotropic electrical characteristics such that conduction is conducted only in an electrode direction (Z direction) when connected, and insulated from adjacent electrodes in a direction between the electrodes (X direction).

When the adhesive is melted by applying heat and pressure to the anisotropic conductive layer 800, the conductive particles are arranged between the input pad and the driving connection wire 630 and between the output pad and the plurality of panel connection wires 730 and 740. In addition, an adhesive may be filled between adjacent electrodes to insulate the adjacent electrodes.

While the inventive concept has been particularly shown and described with reference to embodiments thereof, it will be understood that various changes in form and details may be made therein without departing from the spirit and scope of the following claims.

What is claimed is:

1. A chip-on-film package comprising:
a film substrate having a chip mounting region, an inner lead bonding region arranged within the chip mounting region, and an outer lead bonding region spaced apart from the inner lead bonding region in a first direction, and providing upper and lower surfaces opposite to each other;
a first upper wiring pattern arranged on the upper surface of the film substrate and extending in the first direction from the inner lead bonding region to the outer lead bonding region;
a second upper wiring pattern spaced apart from the first upper wiring pattern in the first direction;
a first wiring via connected to the first upper wiring pattern, penetrating the film substrate and extending toward the lower surface of the film substrate;
a lower wiring pattern connected to the first wiring via on the lower surface of the film substrate, and extending in the first direction;
a second wiring via connected to the second upper wiring pattern, penetrating the film substrate, extending toward a lower surface of the film substrate, and connected to the lower wiring pattern;
an upper solder resist layer covering an upper surface of the first upper wiring pattern; and
a lower solder resist layer covering an upper surface of the lower wiring pattern, wherein the upper surface of the second upper wiring pattern is exposed without being covered by the upper solder resist layer.

2. The chip-on-film package of claim 1, wherein the lower solder resist layer completely covers the upper and side surfaces of the lower wiring pattern.

3. The chip-on-film package of claim 1, wherein a width of the first upper wiring pattern in a second direction perpendicular to the first direction is greater than a width of the second upper wiring pattern in the second direction.

4. The chip-on-film package of claim 1, wherein the first wiring via has a diameter that gradually reduces from the lower surface of the film substrate toward the upper surface of the film substrate.

5. The chip-on-film package of claim 1, wherein a first dimple having a first depth is formed on a surface of the lower wiring pattern.

6. The chip-on-film package of claim 5, wherein a second dimple having a second depth less than the first depth is formed on a surface of the first upper wiring pattern.

7. The chip-on-film package of claim 1, wherein a length of the second upper wiring pattern in the first direction is about 500 micrometers to about 1000 micrometers.

8. The chip-on-film package of claim 1, wherein a lower surface of the first upper wiring pattern is located at the same vertical level as a lower surface of the second upper wiring pattern.

9. The chip-on-film package of claim 1, further comprising:
a semiconductor chip arranged in the chip mounting region of the film substrate,
wherein a part of the first upper wiring pattern overlaps the semiconductor chip in a vertical direction.

10. The chip-on-film package of claim 1, wherein the first wiring via overlaps the upper solder resist layer and the lower solder resist layer in a vertical direction.

11. A chip-on-film package comprising:
a film substrate having an input region, an output region, and a chip mounting region between the input region and the output region, and providing upper and lower surfaces opposite to each other;
a plurality of first upper wiring patterns arranged on the upper surface of the film substrate and extending from the chip mounting region in a first direction to the input region;
a plurality of second upper wiring patterns arranged apart from the plurality of first upper wiring patterns in the first direction;
a plurality of third upper wiring patterns respectively arranged between a pair of first upper wiring patterns arranged adjacent to one another in a second direction perpendicular to the first direction among the plurality of first upper wiring patterns; and
an upper solder resist layer covering upper surfaces of the plurality of first upper wiring patterns and upper surfaces of the plurality of third upper wiring patterns,
wherein upper surfaces of the plurality of second upper wiring patterns are exposed without being covered by the upper solder resist layer.

12. The chip-on-film package of claim 11, further comprising:
a first wiring via connected to each of the plurality of first upper wiring patterns, penetrating the film substrate, and extending toward the lower surface of the film substrate;
a lower wiring pattern connected to the first wiring via on the lower surface of the film substrate and extending in the first direction; and
a second wiring via connected to each of the plurality of second upper wiring patterns, penetrating the film substrate, extending toward a lower surface of the film substrate, and connected to the lower wiring pattern.

13. The chip-on-film package of claim 12, wherein the first wiring via overlaps the upper solder resist layer in a vertical direction, and the second wiring via does not overlap the upper solder resist layer in the vertical direction.

14. The chip-on-film package of claim 11, wherein, in the output region, each of the third upper wiring patterns includes a first portion that does not vertically overlap the upper solder resist layer; and a second portion that vertically overlaps the upper solder resist layer.

15. The chip-on-film package of claim 14, wherein a length of the first portion in the first direction is about 700 micrometers to about 1300 micrometers.

16. The chip-on-film package of claim 13, wherein the plurality of third upper wiring patterns do not overlap with the plurality of second upper wiring patterns in the first direction when viewed in plan view.

17. The chip-on-film package of claim 11, wherein a lower surface of each of the plurality of first upper wiring patterns is located at the same vertical level as a lower surface of each of the plurality of second upper wiring patterns.

18. The chip-on-film package of claim 11, wherein the upper solder resist layer covers one side surface of the plurality of first upper wiring patterns, and the one side faces the third upper wiring pattern.

19. A chip-on-film package comprising:
a film substrate having a chip mounting region, an inner lead bonding region arranged within the chip mounting region, and an outer lead bonding region spaced apart from the inner lead bonding region in a first direction, and providing upper and lower surfaces opposite to each other;
a plurality of first upper wiring patterns arranged on the upper surface of the film substrate, overlapping the inner lead bonding region, extending in the first direction, and overlapping the outer lead bonding region;
a plurality of second upper wiring patterns spaced apart from each of the plurality of first upper wiring patterns in the first direction and in a second direction perpendicular to the first direction;
a first wiring via connected to each of the plurality of first upper wiring patterns, penetrating the film substrate, and extending toward the lower surface of the film substrate;
a lower wiring pattern connected to the first wiring via on the lower surface of the film substrate and extending in the first direction;
a second wiring via connected to each of the plurality of second upper wiring patterns, penetrating the film substrate, extending toward a lower surface of the film substrate, and connected to the lower wiring pattern;
a plurality of third upper wiring patterns respectively arranged between a pair of first upper wiring patterns arranged adjacent in a second direction perpendicular to the first direction among the plurality of first upper wiring patterns;
an upper solder resist layer covering upper surfaces of the plurality of first upper wiring patterns; and
a lower solder resist layer covering an upper surface of the lower wiring pattern,
wherein upper surfaces of the plurality of second upper wiring patterns are exposed without being covered by the upper solder resist layer.

20. The chip-on-film package of claim 19, wherein a first dimple having a first depth is formed on a surface of the lower wiring pattern, and a second dimple having a second depth less than the first depth is formed on a surface of the first upper wiring patterns.
